(19) United States
(12) Patent Application Publication
(10) Pub. No.: US 2026/0144084 A1
(43) Pub. Date: May 21, 2026

(54) FAN-OUT TYPE PACKAGING STRUCTURE AND PACKAGING METHOD

(71) Applicant: JIANGSU PANGU SEMICONDUCTOR TECHNOLOGY CO.LTD, Nanjing (CN)

(72) Inventors: Zhiyi Xiao, Nanjing (CN); Shuying Ma, Nanjing (CN)

(73) Assignee: JIANGSU PANGU SEMICONDUCTOR TECHNOLOGY CO.LTD, Nanjing (CN)

(21) Appl. No.: 19/441,739

(22) Filed: Jan. 6, 2026

Related U.S. Application Data
(63) Continuation of application No. PCT/CN2024/103968, filed on Jul. 5, 2024.

(30) Foreign Application Priority Data
Jul. 7, 2023 (CN) 202310829861.X

(51) Int. Cl. H10W 70/06; H10P 72/70; H10W 70/05; H10W 70/08; H10W 70/655; H10W 70/66; H10W 70/685; H10W 74/01; H10W 74/10; H10W 74/47; H10W 90/00

(52) U.S. Cl. CPC H10W 70/06; H10P 72/7412; H10P 72/743; H10W 70/08; H10W 70/096; H10W 70/655; H10W 70/66; H10W 70/685; H10W 74/014; H10W 74/114; H10W 74/47; H10W 90/724

(57) ABSTRACT

A fan-out type packaging method includes: preparing a carrier substrate, where front and back sides of the carrier substrate are respectively provided with removable structures, forming redistribution layers on the front and back sides of the carrier substrate; mounting chips on the front and back sides of the carrier substrate; removing the carrier substrate and performing cutting to obtain a packaged chip. The present disclosure adopts a packaging process involving simultaneous processing on both sides, forming a symmetrical structure on the front and back sides. This may offset bending, dimensional instability, and other phenomena caused by performance differences between multilayer polymer materials and metal materials; the pre-redistribution layer fan-out packaging process adopted by the present disclosure may address precision issues of high-density wiring fan-out packaging. Additionally, the dual-sided structure may effectively offset warping caused by multilayer wiring.

### CROSS-REFERENCE TO RELATED APPLICATIONS

This application is a continuation of International Application No. PCT/CN2024/103968, filed on Jul. 5, 2024, which claims priority to Chinese Patent Application No. 202310829861.X, filed on Jul. 7, 2023. All of the aforementioned applications are incorporated herein by reference in their entireties.

### TECHNICAL FIELD

The present disclosure relates to the field of semiconductor packaging technologies, and in particular, to a fan-out type packaging structure and packaging method.

### BACKGROUND

Fan-out packaging, based on a fabrication sequence of a die (Die, that is, a bare chip) and a redistribution layer (Redistribution Layer, RDL), may be categorized into three mainstream types: chip-first face-up packaging, chip-first face-down first-chip packaging, and RDL-first face-down packaging.

The RDL-first face-down packaging has the following advantages: the RDL is fabricated directly on a carrier wafer (Carrier Wafer), rather than on a molded reconstituted wafer in another two fan-out packaging types. This facilitates the fabrication of multilayer high-density redistribution layers for ultra-fine wirings, thereby increasing the number of I/So (Input/Outputs) routed out from the packaging and improving product performance. A tested good-quality chip is directly soldered to the pre-prepared under-bump-metal (UBM) on the RDL by using a face-down flip-chip bonding manner, which helps to avoid bare chip shift caused by mold flow impact during a wafer-level molding process that leads to subsequent difficulties in photolithographic alignment. At the same time, a packaging yield is improved, and thus a loss of the chip yield due to a redistribution layer process is avoided.

However, there are performance differences between a plurality of layers of polymer materials and metal materials, leading to phenomena such as warpage and dimensional instability occur in each film layer. Therefore, when the RDL includes two or more layers of redistribution wirings which requires high-density, high-integration packaging, each film layer will warp, and thus ultimately resulting in that the chip yield is reduced.

### SUMMARY

The purpose of the present disclosure is to provide a fan-out type packaging structure and packaging method to solve the above technical problems in the conventional technologies.

To achieve the above purpose, the present disclosure adopts the following technical solution.

A fan-out type packaging method includes:
preparing a carrier substrate, where front and back sides of the carrier substrate are respectively provided with removable structures;
forming redistribution layers respectively on the front and back sides of the carrier substrate;
mounting chips respectively on the front and back sides of the carrier substrate, where the chip is electrically connected to the redistribution layer; and
removing the carrier substrate and cutting to obtain a packaged chip.

Optionally, the forming the redistribution layers respectively on the front and back sides includes:
forming first insulating layers respectively on the removable structures; and
depositing a conductive layer on the first insulating layer and etching the conductive layer to form the redistribution layer, or adhering a prefabricated redistribution wiring to the first insulating layer to form the redistribution layer.

Optionally, an opening is formed on the first insulating layer, and
after forming the first insulating layer, the method also includes: before forming the redistribution layer, forming an underlying solder joint metal layer and an underlying pad metal layer in sequence in the opening of the first insulating layer, where the redistribution layer is electrically connected to the underlying pad metal layer.

Optionally, an opening is formed on the first insulating layer, and
after forming the first insulating layer, the method also includes: forming an underlying pad metal layer in the opening of the first insulating layer, where the redistribution layer is electrically connected to the underlying pad metal layer;
and after removing the carrier substrate, the method also includes: forming an underlying solder joint metal layer on an exposed surface of the underlying pad metal layer, or performing chemical deposition on the exposed surface of the underlying pad metal layer.

Optionally, mounting the chips respectively on the front and back sides of the carrier substrate includes:
forming second insulating layers having an opening respectively on the front and back sides of the carrier substrate;
forming an under bump metal (UBM) pattern on each of the second insulating layers, where the UBM pattern is electrically connected to the redistribution layer through the opening of the second insulating layer; and
mounting the chips respectively on the front and back sides of the carrier substrate and electrically connecting the chip to the UBM pattern.

Optionally, a chip pad metal layer is formed on a connection terminal of the chip, and a chip solder joint metal layer is formed on the chip pad metal layer, where the mounting the chips respectively on the front and back sides of the carrier substrate and electrically connecting the chip to the UBM pattern includes:
soldering the chip to the UBM pattern by the chip solder joint metal layer.

Optionally, a chip pad metal layer is formed on a connection terminal of the chip, and the chip pad metal layer is performed chemical deposition, where the mounting the chips respectively on the front and back sides of the carrier substrate and electrically connecting the chip to the UBM pattern includes:
forming a chip solder joint metal layer on the UBM pattern; and
soldering the chip to the UBM pattern by the chip solder joint metal layer.

Optionally, the soldering the chip to the UBM pattern by the chip solder joint metal layer includes:
soldering the chip to the UBM pattern by the chip solder joint metal layer through a flip-chip bonding process adopting reflow soldering.

Optionally, the removable structures are symmetrical to each other.

Optionally, the redistribution layer includes multilayer redistribution wirings.

Optionally, after mounting the chip and before removing the carrier substrate, the method also includes: performing a plastic encapsulation on the front and back sides of the carrier substrate.

The present disclosure also provides a dual-sided fan-out type packaging structure, including:
a first insulating layer;
a redistribution layer disposed on the first insulating layer;
a second insulating layer disposed on the redistribution layer, the second insulating layer having an opening;
a UBM pattern disposed on the second insulating layer and electrically connected to the redistribution layer through the opening of the second insulating layer;
a chip disposed on the redistribution layer and electrically connected to the UBM pattern; and
a plastic encapsulation layer covering the chip.

### BRIEF DESCRIPTION OF THE DRAWINGS

To more clearly illustrate the technical solutions in the embodiments of the present disclosure, the accompanying drawings required for describing the embodiments will be briefly introduced below. It should be understood that the drawings only show some embodiments of the present application, and should not be regarded as limiting the scope. It should also be understood that, the same or similar reference numerals in the drawings are used for denoting the same or similar elements. It should also be understood that the drawings are schematic, and the dimensions and proportions of the elements in the drawings are not necessarily precise.

FIG. 1 is a schematic diagram of step 1 according to an embodiment of the present disclosure.

FIG. 2 is a schematic diagram of step 2 according to an embodiment of the present disclosure.

FIG. 3 is a schematic diagram of step 3 according to an embodiment of the present disclosure.

FIG. 4 is a schematic diagram of step 4 according to an embodiment of the present disclosure.

FIG. 5 is a schematic diagram of step 5 according to an embodiment of the present disclosure.

FIG. 6 is a schematic diagram of step 6 according to an embodiment of the present disclosure.

FIG. 7 and FIG. 8 are schematic diagrams of step 7 in Embodiment 1 of the present disclosure.

FIG. 9 is a schematic diagram of step 8 according to an embodiment of the present disclosure.

FIG. 10 is a schematic diagram of step 10 according to an embodiment of the present disclosure.

FIG. 11 is another schematic diagram of step 2 according to an embodiment of the present disclosure.

FIG. 12 is another schematic diagram of step 3 according to an embodiment of the present disclosure.

FIG. 13 is another schematic diagram of step 3 according to an embodiment of the present disclosure.

FIG. 14 is a schematic structural diagram of a pre-fabricated redistribution wiring according to an embodiment of the present disclosure.

FIG. 15 is another schematic structural diagram of a redistribution layer according to an embodiment of the present disclosure.

FIG. 16 is another schematic diagram of step 4 according to an embodiment of the present disclosure.

FIG. 17 is another schematic diagram of step 5 according to an embodiment of the present disclosure.

FIG. 18 is another schematic diagram of step 5 according to an embodiment of the present disclosure.

FIG. 19 is another schematic diagram of step 6 according to an embodiment of the present disclosure.

FIG. 20 is a schematic diagram of step 8 according to an embodiment of the present disclosure.

### DETAILED DESCRIPTION OF THE EMBODIMENTS

The present disclosure is described in detail below to make the advantages and features of the present disclosure be more easily understood by those skilled in the art, thereby defining the scope of protection of the present disclosure more clearly and explicitly.

A brief overview of one or more aspects is provided below to offer a basic understanding of these aspects. The overview is not an exhaustive summary of all envisioned aspects, and is neither intended to identify key or decisive elements of all aspects or to attempt to define the scope of any or all aspects. Its sole purpose is to present some concepts of one or more aspects in a simplified form as a prelude to the more detailed description provided later.

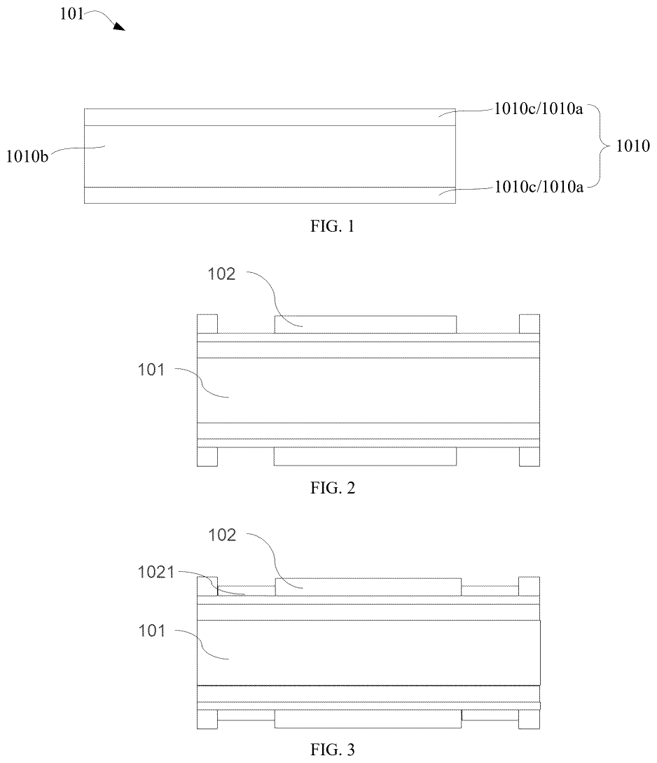

As shown in FIG. 1 to FIG. 10, some embodiments of the present disclosure provide a fan-out type packaging method, which includes the following steps.

Step 1: as shown in FIG. 1, preparing a carrier substrate 101. Among them, the carrier substrate 101 includes an intermediate layer 1010b and mutually symmetrical removable structures 1010 respectively provided on front and back sides of the intermediate layer 1010b. The removable structure 1010 includes a metal foil 1010a or an intermediate layer 1010b. The metal foil 1010a may be a copper foil. The intermediate layer 1010b may be made of one or a combination of silicon, silicon dioxide, various types of glass, metal, or organic materials, which exhibits strong heat resistance and is not prone to deformation.

Step 2: as shown in FIG. 2, forming first insulating layers 102 having an opening respectively on the front and back sides of the carrier substrate 101. Specifically, the first insulating layer 102 is formed by laminating an insulating film or coating an insulating adhesive. A thickness of the first insulating layer 102 may range from 10 μm to 20 μm. The first insulating layer 102 may be made of a photolithographic material, which forms a pattern by exposure and development; or it may be made of a non-photolithographic material, which forms a pattern by laser drilling.

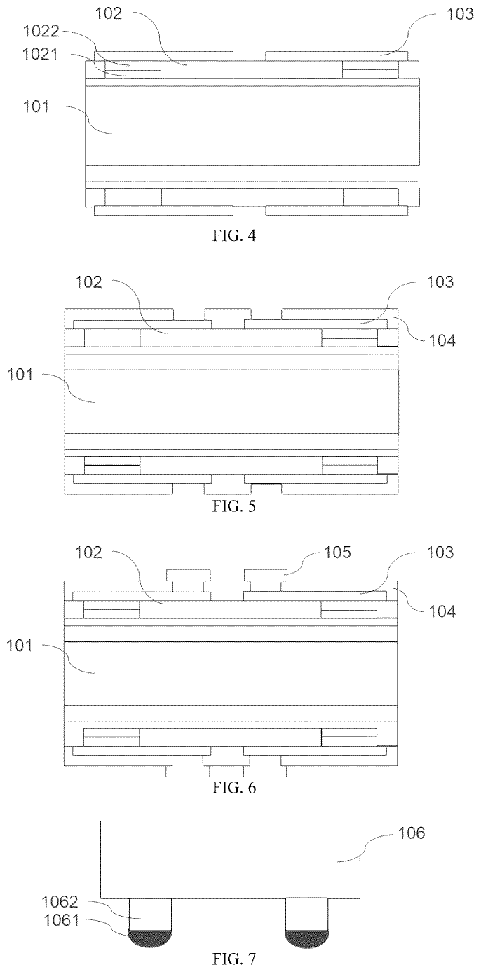

Step 3: as shown in FIG. 3 and FIG. 4, forming an underlying solder joint metal layer 1021 and an underlying pad metal layer 1022 in sequence in the opening of the first insulating layer 102 (formed by exposure and development or laser drilling). Among them, formation manners include, but are not limited to, electroplating and filling with a metallic paste. A thickness of the underlying solder joint metal layer 1021 may be, for example, 10 μm, and a thickness of the underlying pad metal layer 1022 may be, for example, 5 μm. The underlying solder joint metal layer 1021 may be, for example, a tin layer, and the underlying pad metal layer 1022 may be, for example, a copper layer. It should be noted that, materials of the underlying solder joint metal layer 1021 and the underlying pad metal layer 1022 may be the same or different, which is not specifically limited in the embodiments of the present disclosure.

Step 4: as shown in FIG. 4, forming redistribution layers 103 respectively on the front and back sides of the carrier substrate through a redistribution process. Specifically, a conductive layer is first deposited on the carrier substrate. The conductive layer may be formed by chemical deposition or physical sputtering. A material of the conductive layer is copper or titanium/nickel. Then, a photoresist layer is formed. Finally, the redistribution layer 103 is formed by electroplating and etching.

It may be understood that, by repeating step 3 and step 4, single-layer redistribution wiring may be repeatedly formed on the carrier substrate, so that the finally formed redistribution layer 103 includes multilayer redistribution wirings.

Step 5: as shown in FIG. 5, second insulating layers 104 having an opening is formed on the front and back sides of the carrier substrate. The second insulating layer 104 may be made of a photolithographic material, which forms a pattern by exposure and development, or it may be made of a non-photolithographic material, which forms a pattern by laser drilling. Among them, a thickness of the second insulating layer 104 depends on a thickness of the redistribution layer 103. Preferably, the thickness of the second insulating layer 104 exceeds about 10 μm to 20 μm above a metal surface of the redistribution layer 103.

Step 6: as shown in FIG. 6, forming UBM metal layers respectively on the front and back sides of the carrier substrate 101 through the redistribution process. Specifically, the UBM metal layer may be formed by chemical deposition or physical sputtering, and a material of the UBM metal layer is Cu or Ti/Cu. Then a photoresist film layer is formed on the UBM metal layer; finally, a UBM pattern 105 is formed by electroplating and etching the conductive layer, and the UBM pattern 105 is interconnected with the redistribution layer 103 through the opening of the second insulating layer 104.

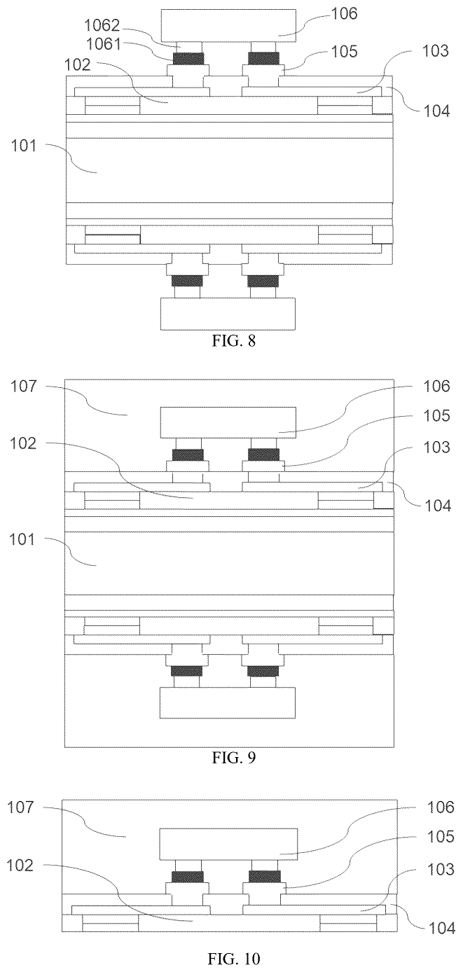

Step 7: as shown in FIG. 7 and FIG. 8, mounting a chip 106 onto the UBM pattern 105 on the front side via a flip-chip bonding process, and soldering the chip 106 with UBM pattern 105 on the front side through reflow soldering. The same operation method is adopted to solder the chip 106 with the UBM pattern 105 on the back side.

In the present embodiment, the chip 106 is prepared as follows: for an IC wafer, a chip pad metal layer 1062 is formed on connection terminals, followed by the formation of a chip solder joint metal layer 1061, and then thinning and dicing are performed to form a single good-quality chip 106. In this manner, the chip 106 is soldered onto the UBM pattern 105 via the chip solder joint metal layer 1061.

In another optional method, as shown in FIG. 16 to FIG. 18, a chip 112 is prepared as follows: for an IC wafer, a chip pad metal layer 1122 is formed on connection terminals, followed by chemical deposition—for example, using nickel and gold, and then thinning and dicing are performed to form a single good-quality chip 112. In this manner, a chip solder joint metal layer 111 is formed on the UBM pattern 110, and the chip 112 is soldered onto the UBM pattern 110 via the chip solder joint metal layer 111.

Among them, the chip pad metal layer 1122 may be, for example, a copper layer, and the chip solder joint metal layer 111 may be, for example, a tin layer.

In addition, the connection terminal may be a wafer pad, a lead-out terminal, a pin header, or a pin, which is a metal region connected to the chip and serves as the input/output interface of the chip, and is used for connecting an internal circuit of the chip to an external circuit.

Step 8: as shown in FIG. 9, forming an encapsulation layer 107 through a panel-level molding process to encapsulate the mounted chip 106.

Step 9: as shown in FIG. 10, removing the carrier substrate 101, and removing the residual copper foil layer on the carrier substrate at a bottom of the insulation layers and wiring layers on the front and back sides by rapid etching; or removing the carrier substrate 101 through a mechanical force, for example, an external force is applied to separate a release film from the insulation layers and the wiring layers on the front and back sides.

Step 10: as shown in FIG. 10, cutting to separate the structure into packaged chips. Thereafter, testing and packaging for shipment may be carried out.

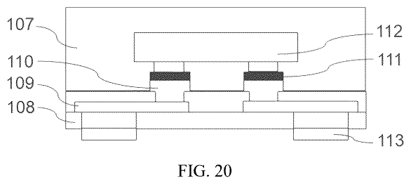

As an optional implementation, as shown in FIG. 12, only an underlying pad metal layer 1082 may be formed in an opening of a first insulating layer 108, and the underlying pad metal layer 1082 may be, for example, a copper layer. In this implementation, as shown in FIG. 20, after removing the carrier substrate, the underlying pad metal layer 1082 is exposed from the opening of the first insulating layer 108. At this time, an underlying solder joint metal layer 113 may be formed on an exposed surface of the underlying pad metal layer 1082, or nickel and gold may be used to perform chemical deposition on the exposed surface of the underlying pad metal layer 1082 to prevent oxidation of the exposed underlying pad metal layer 1082.

As shown in FIG. 10, Embodiment 1 also provides a fan-out type packaging structure, which includes:
a redistribution layer 103; and
a chip 106, disposed on the redistribution layer 103 and electrically connected to the redistribution layer 103.

Optionally, the packaging structure also includes:
a first insulating layer 102, where an opening is formed on the first insulating layer 102, and an underlying solder joint metal layer 1021 and an underlying pad metal layer 1022 are formed in the opening, and the redistribution layer 103 is electrically connected to the underlying pad metal layer 1022;
a second insulating layer 104 disposed between the redistribution layer 103 and the chip 106 and having an opening;
a UBM pattern 105 disposed between the second insulating layer 104 and the chip 106 and is electrically connected to the redistribution layer 103 via the opening of the second insulating layer 104, and the chip 106 is electrically connected to the UBM pattern 105, where the chip 106 is mounted onto the UBM pattern 105 via a flip-chip bonding process, and the chip 106 is soldered with the UBM pattern 105 through reflow soldering; and
an encapsulation layer 107 covering the chip 106.

Among them, the underlying solder joint metal layer 1021 may be, for example, a tin layer, and the underlying pad metal layer 1022 may be, for example, a copper layer.

As shown in FIG. 1 and FIG. 11 to FIG. 20, some embodiments of the present disclosure provide another fan-out type packaging method, including the following steps:

Step 1: as shown in FIG. 1, preparing a carrier substrate 101. Among them, the carrier substrate 101 includes an intermediate layer 1010b and mutually symmetrical removable structures 1010 respectively provided on front and back sides of the intermediate layer 1010b. The removable structure 1010 including a metal foil 1010a or a release film 1010c. The metal foil may be a copper foil, and the intermediate layer may be made of one or a combination of silicon, silicon dioxide, various types of glass, metal, or organic materials, which exhibits strong heat resistance and is not prone to deformation.

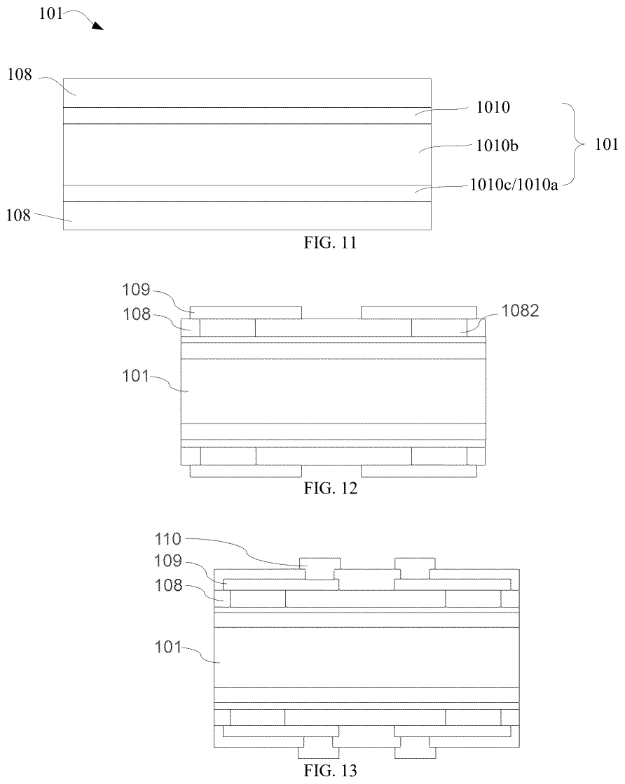

Step 2: as shown in FIG. 11, forming a first insulating layer on the carrier substrate 101. In the present embodiment, the first insulating layer is an adhesive layer 108. A material of the adhesive layer 108 may be an adhesive insulating glue.

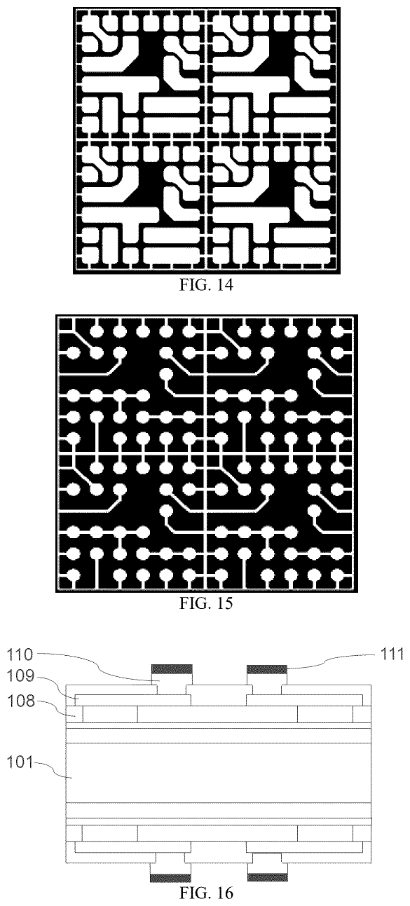

Step 3: as shown in FIG. 12, adhering a pre-fabricated redistribution wiring (refer to FIG. 14) onto the adhesive layer 108 to form a redistribution layer 109 (refer to FIG. 15). Specifically, an opening is formed on the adhesive layer 108 by drilling, and an underlying pad metal layer 1082 is formed in the opening via chemical deposition or PVD, thereby enabling the pre-fabricated redistribution wiring to adhere onto the adhesive layer 108 and electrically connect to the underlying pad metal layer 1082 in the opening.

It should be noted that by repeating the above Steps 2 and 3, a redistribution layer 109 including multilayer redistribution wirings may be formed.

Step 4: as shown in FIG. 13, forming a second insulating layer having an opening on the redistribution layer 109, and a UBM pattern 110 is formed on the second insulating layer. The UBM pattern 110 is electrically connected to the redistribution layer 109 via the opening on the second insulating layer.

Step 5: as shown in FIG. 16, forming a chip solder joint metal layer 111 on the UBM pattern 110, where the chip solder joint metal layer 111 may be a tin metal layer.

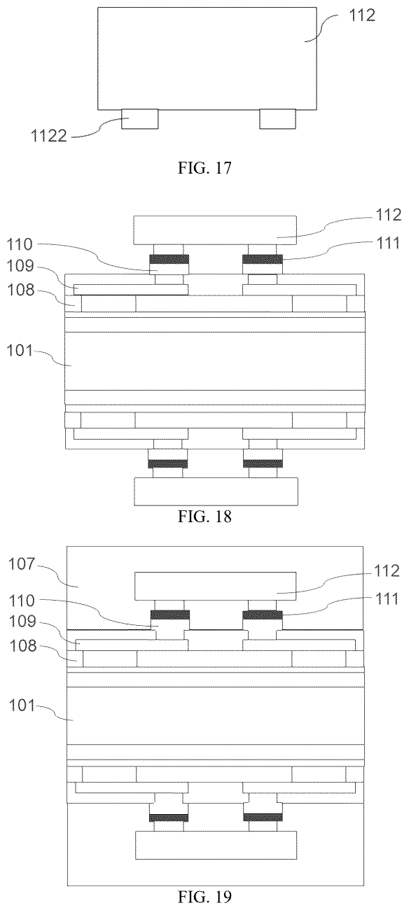

Step 6: as shown in FIG. 17 and FIG. 18, mounting a single chip 112 onto the chip solder joint metal layer 111 on the front side via a flip-chip bonding process. The front-side chip 112 is soldered onto the front-side UBM pattern 110 via the chip solder joint metal layer 111 through reflow soldering. By adopting the same method, on the back side, the chip 112 is soldered onto the back-side UBM pattern 110 via the chip solder joint metal layer 111. Among them, the chip preparation process includes: for an IC wafer, forming a chip pad metal layer 1122 in a connection terminal area, performing chemical deposition with NiAu on the chip pad metal layer 1122, and then performing thinning and dicing to form the chip 112.

Step 7: as shown in FIG. 19, forming an encapsulation layer 107 through a panel-level molding process to encapsulate the mounted chip 112. Molding may be performed on the front side and the back side sequentially, or may be performed simultaneously on the front and back sides through the design and development of molding molds and process, thereby eliminating warpage problems that may arise after single-side encapsulation.

Step 8: as shown in FIG. 20, removing the carrier substrate 101, and removing the residual copper foil layer on the carrier substrate at a bottom of the insulating adhesive films and wiring layers on the front and back sides by rapid etching; or removing the carrier substrate through a mechanical force, for example, an external force is applied to separate a release film 1010c from the insulating adhesives and the wiring layers on the front and back sides. Then, chemical deposition with nickel-gold is performed on an exposed surface of the chip pad metal layer 1082 to prevent oxidation of the chip pad metal layer 1082.

Step 9: as shown in FIG. 20, cutting to separate the structure into packaged chips. Thereafter, testing and packaging for shipment may be carried out.

As shown in FIG. 20, some embodiments of the present disclosure also provide another fan-out type packaging structure, which includes:
a redistribution layer 109 disposed on an adhesive layer 108, where the redistribution layer 109 is formed by a pre-prepared redistribution wiring; and
a chip 112 disposed on the redistribution layer 109 and electrically connected to the redistribution layer 109.

Optionally, the packaging structure may also include:
an adhesive layer 108 disposed underneath the redistribution layer 109;
a second insulating layer disposed between the redistribution layer 109 and the chip 112;
a UBM pattern 110 disposed between the second insulating layer and the chip 112, where the UBM pattern 110 is electrically connected to the redistribution layer, and the chip is electrically connected to the UBM pattern 110; and
an encapsulation layer 107, covering the chip 112.

The present disclosure discloses a fan-out type packaging method, which adopts a packaging process that simultaneously processes two sides to form symmetrical structures on the front and back sides. This may solve warpage, dimensional instability, and other problems caused by performance differences among the plurality of layers of polymer materials and metal materials, thereby improving a processing efficiency. The output of packaged chips is doubled, thereby effectively reducing packaging costs. The RDL-first fan-out packaging process may address precision issues of fan-out packaging with high-density wiring. Additionally, the symmetrical structures on the front and back sides may effectively offset the warpage caused by multilayer wiring. Therefore, the dual-sided pre-redistribution layer fan-out structure is more conducive to meeting the high-density and high-integration packaging requirements for multilayer redistribution layers with two or more layers of redistribution wirings.

The present disclosure discloses a fan-out type packaging method. During the early stage of forming the redistribution layer on the carrier substrate, Sn may be electroplated first, and then Cu is electroplated. Alternatively, spot soldering and copper paste the openings of the insulation layer are filled by adopting method such as solder paste dispensing and copper paste application, thereby avoiding warping issues caused by subsequent processing after removing the carrier substrate, so that process risks are reduced, and thus improving a production efficiency.

The present disclosure discloses a fan-out type packaging method. Compared to traditional flip-chip (FC) bumping chip processes, electroless NiAu plating on copper pads is employed, which may reduce the cost associated with forming bumps on traditional Integrated Circuit (IC) wafers while simultaneously meeting the requirements for good soldering performance. At the same time, during the redistribution layer formation stage, the redistribution wiring may be stamped on a copper foil, and then the pre-fabricated redistribution wiring is adhered to the carrier substrate. Subsequently, interconnections between underlying connection devices and the redistribution layer may be achieved by drilling, chemical deposition, or physical vapor deposition (PVD), thereby reducing the costs of forming the redistribution layer and the insulating adhesive, and thus shortening overall process cycle.

Parts or structures not specifically described in the present disclosure may be implemented by using existing technology or products, and will not be repeat herein.

The above description is only the embodiments of the present disclosure, and is not intend to limit the patent scope of the present disclosure. Any equivalent structural or process transformations based on the content of the specification of the present disclosure, or direct or indirect applications in other related technical fields, will similarly fall within the patent protection scope of the present disclosure.

What is claimed is:

1. A fan-out type packaging method, comprising:
preparing a carrier substrate, wherein the carrier substrate comprises an intermediate layer and removable structures respectively provided on front and back sides of the intermediate layer;
forming redistribution layers respectively on the front and back sides of the carrier substrate;
mounting chips respectively on the front and back sides of the carrier substrate, wherein the chip is electrically connected to the redistribution layer; and
removing the carrier substrate and cutting to obtain a packaged chip.

2. The fan-out type packaging method according to claim 1, wherein the forming the redistribution layers respectively on the front and back sides comprises:
forming first insulating layers respectively on the removable structures; and
depositing a conductive layer on the first insulating layer and etching the conductive layer to form the redistribution layer, or adhering a prefabricated redistribution wiring to the first insulating layer to form the redistribution layer.

3. The fan-out type packaging method according to claim 2, wherein an opening is formed on the first insulating layer, and
after forming the first insulating layer, the method further comprises: forming an underlying solder joint metal layer and an underlying pad metal layer in sequence in the opening of the first insulating layer, wherein the redistribution layer is electrically connected to the underlying pad metal layer.

4. The fan-out type packaging method according to claim 2, wherein an opening is formed on the first insulating layer,
after forming the first insulating layer, the method further comprises: forming an underlying pad metal layer in the opening of the first insulating layer, wherein the redistribution layer is electrically connected to the underlying pad metal layer; and
after removing the carrier substrate, the method further comprises: forming an underlying solder joint metal layer on an exposed surface of the underlying pad metal layer.

5. The fan-out type packaging method according to claim 2, wherein an opening is formed on the first insulating layer, and after forming the first insulating layer, the packaging method further comprises: forming an underlying pad metal layer in the opening of the first insulating layer, wherein the redistribution layer is electrically connected to the underlying pad metal layer; and
after removing the carrier substrate, the method further comprises: performing chemical deposition on the exposed surface of the underlying pad metal layer.

6. The fan-out type packaging method according to claim 2, wherein a thickness of the first insulating layer ranges from 10 μm to 20 μm.

7. The fan-out type packaging method according to claim 4, wherein a thickness of the underlying solder joint metal layer is 10 μm.

8. The fan-out type packaging method according to claim 4, wherein the underlying solder joint metal layer is a tin layer, and the underlying pad metal layer is a copper layer.

9. The fan-out type packaging method according to claim 1, wherein the mounting the chips respectively on the front and back sides of the carrier substrate comprises:
forming second insulating layers having an opening respectively on the front and back sides of the carrier substrate;
forming an under bump metal (UBM) pattern on each of the second insulating layers, wherein the UBM pattern is electrically connected to the redistribution layer through the opening of the second insulating layer; and
mounting the chips respectively on the front and back sides of the carrier substrate and electrically connecting the chip to the UBM pattern.

10. The fan-out type packaging method according to claim 9, wherein a chip pad metal layer is formed on a connection terminal of the chip, and a chip solder joint metal layer is formed on the chip pad metal layer, wherein the mounting the chips respectively on the front and back sides of the carrier substrate and electrically connecting the chip to the UBM pattern comprises:
soldering the chip to the UBM pattern by the chip solder joint metal layer.

11. The fan-out type packaging method according to claim 9, wherein a chip pad metal layer is formed on a connection terminal of the chip, and the chip pad metal layer is performed chemical deposition, wherein the mounting the chips respectively on the front and back sides of the carrier substrate and electrically connecting the chip to the UBM pattern comprises:
forming a chip solder joint metal layer on the UBM pattern; and
soldering the chip to the UBM pattern by the chip solder joint metal layer.

12. The fan-out type packaging method according to claim 9, wherein the soldering the chip to the UBM pattern by the chip solder joint metal layer comprises:
soldering the chip to the UBM pattern by the chip solder joint metal layer through a flip-chip bonding process adopting reflow soldering.

13. The fan-out type packaging method according to claim 1, wherein the removable structures are symmetrical to each other.

14. The fan-out type packaging method according to claim 1, wherein the redistribution layer comprises multilayer redistribution wirings.

15. The fan-out type packaging method according to claim 1, wherein after mounting the chip and before removing the carrier substrate, the method further comprises:
performing a plastic encapsulation on the front and back sides of the carrier substrate.

16. The fan-out type packaging method according to claim 1, wherein the removable structure comprises a metal foil layer.

17. The fan-out type packaging method according to claim 16, wherein the metal foil layer is a copper foil.

18. The fan-out type packaging method according to claim 1, wherein the intermediate layer is made from one or more of silicon, silicon dioxide, glass, metal, or organic materials.

19. The fan-out type packaging method according to claim 1, wherein the removable structure comprises a release film.

20. A fan-out type packaging structure, comprising:
a first insulating layer;
a redistribution layer disposed on the first insulating layer;
a second insulating layer disposed on the redistribution layer, the second insulating layer having an opening;
a UBM pattern disposed on the second insulating layer and electrically connected to the redistribution layer through the opening of the second insulating layer;
a chip disposed on the redistribution layer and electrically connected to the UBM pattern; and
a plastic encapsulation layer covering the chip.
